(19) United States
(12) Patent Application Publication
(10) Pub. No.: US 2008/0101683 A1
(43) Pub. Date: May 1, 2008

(54) System and method of evaluating uncoated turbine engine components

(75) Inventors: Paul J. Zombo, Cocoa, FL (US); Michael Twerdochlib, Oviedo, FL (US); Jan P. Smed, Winter Springs, FL (US); Dennis H. Lemieux, Casselberry, FL (US); Evangelos V. Diatzikis, Chuluota, FL (US); Hans-Gerd Brummel, Berlin (DE)

Correspondence Address: Siemens Corporation;Intellectual Property Department, 170 Wood Avenue South, Iselin, NJ, 08830, US

(73) Assignee: Siemens Power Generation, Inc.

(21) Appl. No.: 11/800,789

(22) Filed: May 7, 2007

Related U.S. Application Data
(63) Continuation-in-part of application No. 10/610,214, filed on Jun. 30, 2003.
Application No. 10/610,214 is a continuation-in-part of application No. 09/470,123, filed on Dec. 22, 1999, now abandoned.

(51) Int. Cl. G01M 15/14; G01N 25/72; G06K 9/00; G02F 1/01; H01L 31/00

(52) U.S. Cl. 382/141; 374/4; 250/330

(57) ABSTRACT

Aspects of the invention are directed to a visual-based system and method for non-destructively evaluating an uncoated turbine engine component. Aspects of the invention are well suited for high speed, high temperature components. Radiant energy emitted from an uncoated turbine engine component can be captured remotely and converted into a useful form, such as a high resolution image of the component. A plurality of images of the component can be captured over time and evaluated to identify failure modes. The system can also measure and map the temperature and/or radiance of the component. The system can facilitate the non-destructive evaluation of uncoated turbine components during engine operation without disassembly of the engine, thereby providing significant time and cost savings. Further, the system presents data to a user with sufficient context that allows an engine operator can evaluate the information with an increased degree of confidence and certainty.

### CROSS-REFERENCE TO RELATED APPLICATIONS

This application is a continuation-in-part of U.S. patent application Ser. No. 10/610,214, filed Jun. 30, 2003, which is a continuation-in-part of U.S. patent application Ser. No. 09/470,123, filed Dec. 22, 1999.

### STATEMENT REGARDING FEDERALLY SPONSORED DEVELOPMENT

Development for this invention was supported in part by Contract No. DE-FC26-01NT41232 awarded by the United States Department of Energy. Accordingly, the United States Government may have certain rights in this invention.

### FIELD OF THE INVENTION

The invention relates in general to turbine engines and, more particularly, to an on-line system of monitoring high speed and/or high temperature turbine engine components.

### BACKGROUND OF THE INVENTION

Turbine engine components can operate in high temperature conditions, which can be in the range of about 800 degrees Celsius to about 1600 degrees Celsius. In addition, many turbine engine components can move at high speeds, such as at about 3600 rpm, during engine operation. Turbine engine components that operate in a high temperature environment and/or at high speeds are difficult to monitor, inspect or otherwise evaluate while the engine is on-line. As a result, it has been common practice to shut down the engine so that an off-line evaluation can be performed.

However, off-line evaluation can be time consuming, labor intensive and expensive because, among other things, it may require a full or partial disassembly of the engine. Moreover, in some instances, an off-line analysis of a component can obscure useful information about certain features, defects and modes of growth. Indeed, many features, defects and modes of growth are not exhibited unless observed in the operational environment. For example, some defect modes produce excessive heat locally at the defect. Such a defect would not be revealed in an off-line inspection. Thus, there is a need for a system that can facilitate the non-destructive evaluation of high-temperature and/or moving turbine components during engine operation and in other instances without disassembly of the engine.

### SUMMARY OF THE INVENTION

In one respect, aspects of the invention are directed to a non-destructive evaluation system. The system applies to an on-line turbine engine, that is, a turbine engine in operation. Within the turbine engine, there is an uncoated component, which emits radiance energy. According to aspects of the invention, an electromagnetic sensor is positioned to receive radiance energy emitted from the uncoated component. The electromagnetic sensor can be, for example, a focal plane array sensor.

The electromagnetic sensor is located remotely from the uncoated component such that there is no contact between the electromagnetic sensor and the component. The electromagnetic sensor is adapted to receive electromagnetic energy from about 0.38 μm to about 15 μm. In one embodiment, the electromagnetic sensor can receive radiance energy at wavelengths from about 0.6 μm to about 2 μm. The electromagnetic sensor produces signals in response to receiving radiance energy. A signal processor is operatively connected to receive signals from the electromagnetic sensor. The signal processor converts the signals into data, which is an image of the uncoated component, a temperature value and/or a radiance value.

In one embodiment, the signal processor can generate images of the uncoated component. The expert system can include a defect detection system that analyzes at least one of the images to identify a defect associated with the uncoated component. The expert system can include a life processor. The life processor can estimate the remaining life of the uncoated component.

In another embodiment, the signal processor can generate temperature values. In such case, the expert system can includes a temperature mapping system. The temperature mapping system can generate a temperature map of a surface of the uncoated component based on the temperature values. Alternatively or in addition to the above, the signal processor can generates radiance values. Accordingly, the expert system can include a radiance mapping system which can generate a radiance map of a surface of the uncoated component based on the radiance values.

The system can further include a data acquisition and analysis system operatively connected to receive data from the signal processor. The data acquisition and analysis system can stores the data. An expert system can be operatively connected to the data acquisition and analysis system. The expert system can analyze data stored by the data acquisition and analysis system.

In another respect, aspects of the invention relate to a method of non-destructively evaluating uncoated turbine engine components during engine operation. According to this method, a turbine engine is operated. The turbine engine includes an uncoated component. A first image of the uncoated component is captured while the turbine engine is operating. The first image is displayed to a user. The first image of the uncoated component can be evaluated to identify a failure mode associated with the uncoated component.

In one embodiment, a plurality of subsequent images of the uncoated component can be captured over a period of time. The first and subsequent images can be captured at wavelengths from about 0.6 μm to about 2 μm. The first image and the plurality of subsequent images of the uncoated component can be sequentially displayed. The displayed images can be compared to identify a failure mode associated with the uncoated component. Such comparing can be performed by an engine operator, a machine vision system and/or an expert software system. When a failure mode is identified, the remaining life of the uncoated component and/or the remaining operating time available can be estimated. An output corresponding to the remaining life of the uncoated component and/or the remaining operating time available can be generated.

In still another respect, aspects of the invention are directed to a method of non-destructively evaluating an uncoated turbine engine component. According to aspects of the invention, a turbine engine is operated. The turbine engine has an uncoated component with a surface. At a first time when the engine is in operation, radiance energy emitted from an area of the surface of the uncoated component is received. In one embodiment, the radiant energy can be received at wavelengths from about 0.6 μm to about 2 μm. Based on the radiance energy received from the uncoated component at the first time, a plurality of first temperature values across the area of the surface is determined. A first temperature map of the area at the first time is generated based on the plurality of first temperature values.

In one embodiment, a temperature measurement device can be provided at a first position on the surface of the uncoated component. The first position can be located in the area. A temperature value at the first position can be measured using the temperature measurement device at the first time. The difference between the temperature value measured by the temperature measurement device and at least one of the first temperature values in the area substantially at the first position can be determined. An output corresponding to the determined difference can be generated.

Additionally, radiance energy emitted from the area of the uncoated component can be received at a subsequent time. A plurality of subsequent temperature values across the area can be determined based on the radiance energy received from the uncoated component at the subsequent time. A subsequent temperature map of the area at the subsequent time can be generated based on the plurality of subsequent temperature values. The first temperature map and/or the subsequent temperature map can be evaluated to identify a failure mode associated with the uncoated component in the area.

### BRIEF DESCRIPTION OF THE DRAWINGS

FIG. 1 is cross-sectional view partially diagrammatic of a system for evaluating uncoated turbine engine components according to aspects of the invention.

FIG. 2 is a view of an electromagnetic energy sensor receiving radiance emitted from an uncoated turbine engine component in accordance with aspects of the invention.

FIG. 3 is a diagrammatic view of a data acquisition and analysis system according to aspects of the invention.

FIG. 4 is an isometric view of a portion of a turbine blade imaged in the circumferential direction by a known line scan device.

FIG. 5 is an isometric view of a region of a turbine blade imaged in accordance with aspects of the invention.

### DETAILED DESCRIPTION OF EMBODIMENTS OF THE INVENTION

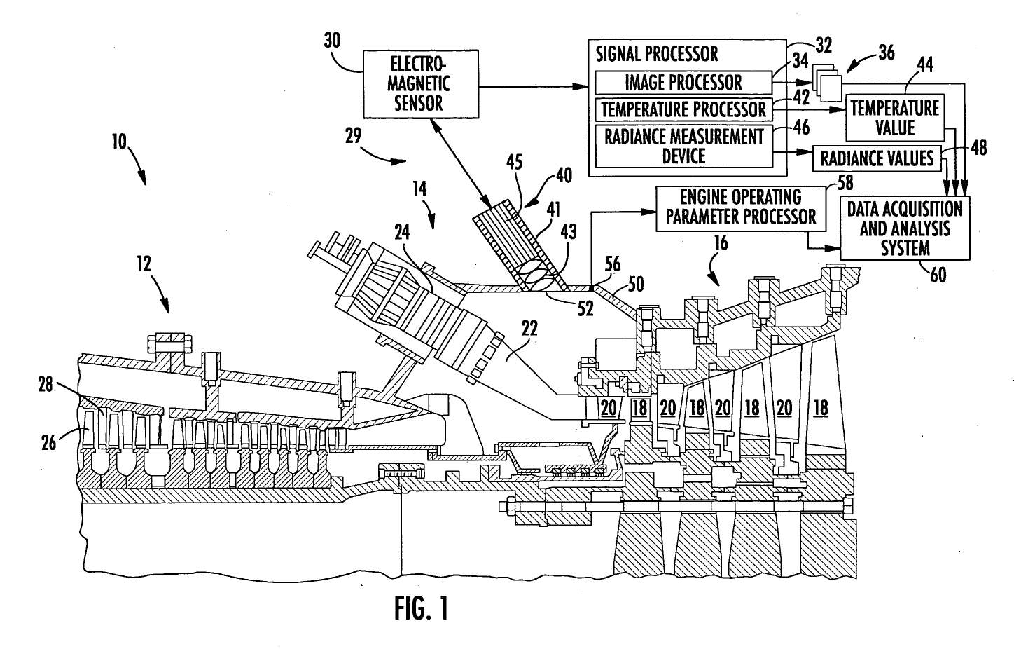

Aspects of this invention are directed to a visual-based system for evaluating uncoated turbine engine components. Embodiments of the invention will be explained in the context of one possible system, but the detailed description is intended only as exemplary. Embodiments of the invention are shown in FIGS. 1-3 and 5, but the present invention is not limited to the illustrated structure or application.

Aspects of the invention are particularly suited for evaluating any high speed and/or high temperature, uncoated component in a turbine engine. A system according to aspects of the invention is to be distinguished from systems that are used to evaluate the condition of a coating, such as a thermal insulating coating, on a high speed and/or high temperature turbine engine component.

FIG. 1 shows an example of a turbine engine 10. The turbine engine 10 can have a compressor section 12, a combustor section 14 and a turbine section 16. In one embodiment, a system according to aspects of the invention can be used to monitor and evaluate one or more rotating turbine blades 18 in the turbine section 16. During engine operation, the turbine blades 18 can move at supersonic speeds of approximately Mach 1.2 or about 890 miles per hour. The turbine blades 18 can be made of, for example, a nickel-based super alloy. According to aspects of the invention, the turbine blade 18 is uncoated. Thus, the base material of the turbine blade 18 is exposed to the operational environment of the engine. Under normal operating conditions, the surface temperature of an uncoated turbine blade 18 can be about 850 degrees Celsius.

It will be understood that aspects of the invention are not limited to use in connection with turbine blades 18, rotating components or even components in the turbine section 16 of the engine 10. For instance, the system according to aspects of the invention can be used in connection with stationary components in the turbine section 16, such as one or more turbine vanes 20. Further, aspects of the invention can be used in connection with various components in the combustor section 14, including, for example, transition ducts 22, baskets 24, and fuel injectors (not shown). Aspects of the invention can also be used in connection with components in the compressor section 12, such as compressor blades 26 and vanes 28. These uncoated components can be made of any of a number of materials, including metals, super alloys, ceramic or ceramic matrix composites, just to name a few possibilities.

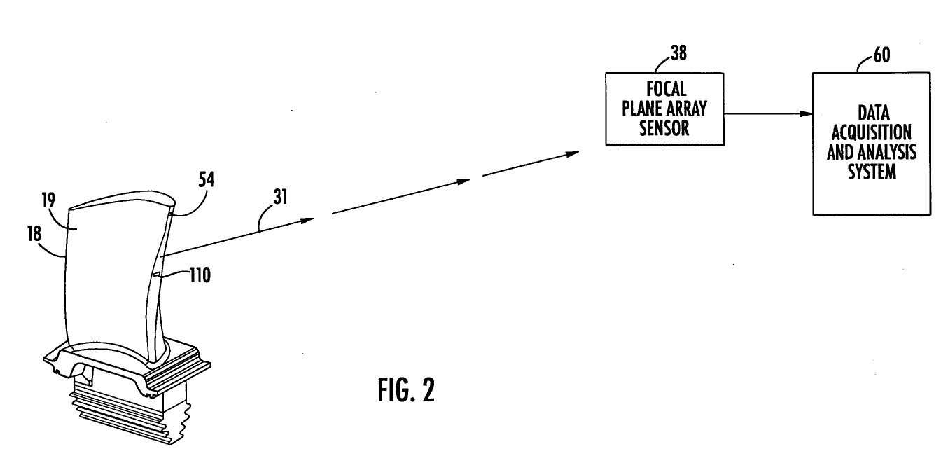

A system 29 according to aspects of the invention can include one or more electromagnetic sensors 30. The electromagnetic sensors 30 can be operatively positioned to have a direct line of sight to an uncoated component under observation. Further, the electromagnetic sensors 30 are spaced from the uncoated component under observation so that there is no physical contact between them. The electromagnetic sensors 30 can remotely capture radiance 31 emitted directly from the surface of the uncoated component under observation, as shown in FIG. 2. It will be understood that use of the term “radiance” is intended to mean the total reflected energy and emitted energy from the surface of the component of interest. Reflected energy is electromagnetic energy that undergoes a redirection, with substantially no change in phase upon interaction with the surface of the component under observation.

The electromagnetic sensors 30 can capture emitted radiance at any desired moment in time. Further, the electromagnetic sensors 30 can capture emitted radiance in any desired electromagnetic spectral window, including, for example, infrared, ultraviolet and visible. The electromagnetic sensor 30 can be dedicated to receiving emitted radiance 31 from only a specific portion of the electromagnetic spectrum, or it can be configured to receive emitted radiance in any band selected by the user. The selection of the bandwidth can be made to enhance the detection of features of interest or perturbations that may occur on or under the component surface 19.

In a system according to aspects of the invention, the sensors 30 can capture electromagnetic energy in any and all spectra. However, aspects of the invention are especially suited for the visual and infrared bands of the electromagnetic spectrum. In one embodiment, the sensors 30 can be adapted to capture electromagnetic energy from about 0.38 to about 14 μm. In another embodiment, the sensors 30 can be adapted to capture electromagnetic energy in the infrared spectrum, from about 0.7 to about 14 μm. The sensors 30 can be adapted to capture electromagnetic energy from a particular portion of the infrared spectrum, such as the near infrared, short infrared, middle infrared and/or long infrared.

Many uncoated turbine engine components are made of metal, which can exhibit a relatively high emissivity compared to components having a ceramic coating. Based on studies of the emittance within various wavelengths within the range from about 0.6 μm to about 15 μm, it has been determined that the near infrared band, e.g., from about 0.6 μm to about 2 μm, is preferred for uncoated components. Within this band, higher levels of emittance can be observed. There are still other bandwidths that are well suited for use in a system according to aspects of the invention, including from about 3 μm to about 5 μm, or from about 8 μm to about 12 μm. Experience has surprisingly revealed that uncoated components are best imaged in the lower bandwidths, such as from about 0.9 μm to about 2 μm or the near infrared.

The emitted radiance 31 from the component under observation can be directly received by the electromagnetic sensors 30. However, in some areas, the engine environment may present conditions that exceed the operational limit of the electromagnetic sensors 30. In such case, the electromagnetic energy can be directed to the sensors 30 by an intermediate device. For example, the electromagnetic energy can be directed to the sensors 30 by a borescope 40. The borescope 40 can include a housing 41 in which one or more lenses 43 are disposed. These lenses 43 can be selected to achieve the desired optical characteristics, such as focal range and field of view. Alternatively, the borescope 40 can include a coherent fiber bundle 45 in the housing 41. The fibers 45 in the bundle may be flexible or rigid. Ideally, the borescope 40 is positioned so that there is a direct line of sight between the borescope 40 and the uncoated component under observation and so that there is no physical contact between the borescope 40 and the component.

The electromagnetic sensor 30 can produce signals in response to receiving radiance energy 31. The electromagnetic sensor 30 can be operatively connected to one or more signal processors 32, as shown in FIG. 1. The signal processors 32 can receive the signals from the electromagnetic sensors 30. The signal processor 32 can be any device that converts the signals received by the electromagnetic sensor 30 into a usable form. For example, in one embodiment, the signal processor 32 can be an image processor 34.

The image processor 34 can generate an image 36 or picture of the uncoated component of interest based on the radiance 31 captured by the electromagnetic sensor 30. Preferably, the image processor 34 can have sufficient resolution to allow for identification and/or characterization of key features of the component under observation. In order to obtain the resolution needed of a moving turbine engine component, such as a turbine blade 18, the image processor 34 should be able to process the radiance 31 received by the electromagnetic sensor 30 within about 30 microseconds or less. Otherwise, spatial distortions or image blur can occur, potentially rendering the image 36 useless.

Because some of the uncoated components under observation move at high speeds, the image processor 34 can be adapted for high speed imaging. To that end, the imaging processor 34 can be equipped to take a snapshot of the component. That is, the imaging processor 34 can capture all information from substantially every imaging pixel of the uncoated component being imaged at substantially the same instant in time. However, the system 29 according to aspects of the invention can be configured to allow the exposure settings to be adjusted.

It should be noted that the electromagnetic sensor 30 and the image processor 34 can be separate devices, or they can be part of a single device. In one embodiment, at least the electromagnetic sensor 30 can be a focal plane array sensor 38 (e.g., an array of charged coupled devices (CCD)). Examples of a focal plane array sensor include the FLIR Phoenix and the FLIR Alpha, which are available from FLIR Systems, Inc., Wilsonville, Oreg. The focal plane array sensor 38 can measure emitted radiance 31 from at least a portion of the surface 19 of the component under observation. The focal plane array sensor 38 is particularly well suited for imaging components in the infrared part of the spectrum. The image processor 34 can render a coherent spatial image of the object in the desired spectral band.

It should be noted that the terms “focal plane array sensor” or “electromagnetic sensor,” as used herein, are intended to specifically exclude point source scan, line scan or A-scan sensors, including pyrometers that scan in these manners. Such sensors only provide data about a single point or a single line on the surface of the component under observation. Such information is not complete, introduces uncertainties and is prone to misinterpretation.

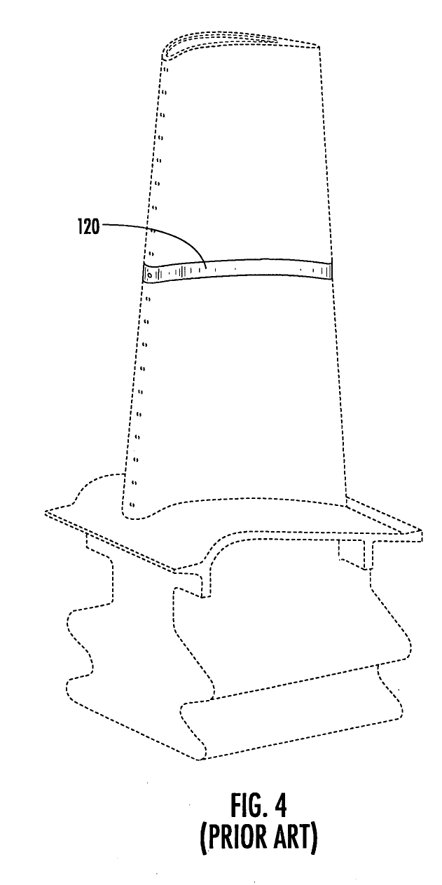

As an illustration, assume that a user wanted to collect data on or capture an image of a single point or line at a particular radial elevation on a blade (relative to the axis of rotation of the blade). If data on or an image of a single point or line on a turbine blade were obtained, there is no guarantee that the actual intended point on the blade is being captured is because no other context is provided. For example, a user may intend to collect data on the tenth cooling hole (from the axis of rotation) in a series of cooling holes extending radially along a turbine blade. But, operational factors, including centrifugal forces and thermal expansion, can affect the actual position of intended target hole. Thus, the user may be actually be viewing the, ninth cooling hole or the eleventh cooling hole instead of the tenth cooling hole. A graphical representation of a line scan is shown in FIG. 4. It can be seen that data concerning only a narrow band 120 of the blade surface, usually no more than 5 millimeters wide, is obtained. Because insufficient context is provided, a user may have to resort to guesswork as to what hole is actually being imaged. Consequently, systems have been designed or are operated with overly large safety factors, which, in turn, can appreciably increase the cost of the system.

In addition to not providing sufficient spatial context, a line scan may sufficiently obtain all data relating to features that are larger than the width of the line region scanned. Further, a line scan or A-scan can only obtain data in the circumferential direction (the direction of rotation) of the component under observation. As a result, the potential data that could be collected is severely limited. For instance, an operator may want to scan features that lie in a radial path, such as the leading edge cooling holes. A radial scan of such features is not possible with point source scan, line scan or A-scan sensors.

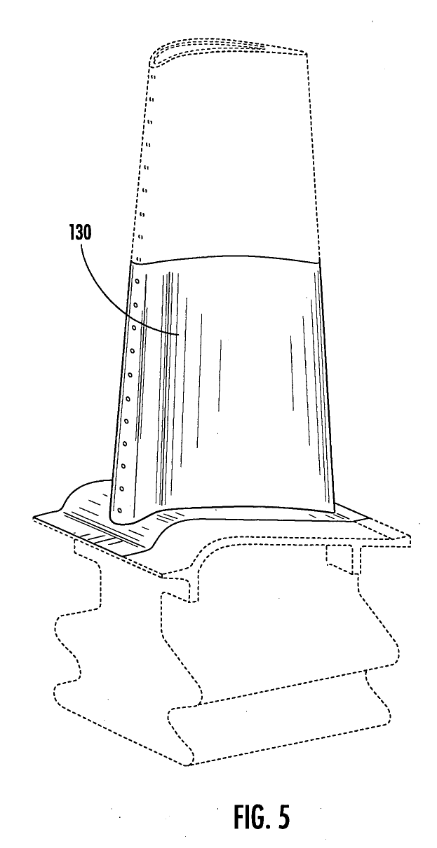

In contrast, the image processor 34 according to aspects of the invention can generate an image 36 of an entire component or at least a significant area of the component, thereby providing more information and context than what would be provided by point source scan, line scan or A-scan sensors, including pyrometers that scan in these manners. Thus, the image 36 can be evaluated and understood with a higher degree of confidence and certainty, so as to minimize the reliance on guesswork. A graphical example of an area of coverage 130 of a turbine blade captured by the system 29 according to aspects of the invention is shown in FIG. 5. The area 130 can be large enough to provide a user with sufficient spatial context and information.

Further, examples of on-line images are shown on pages 15 and 16 of a presentation entitled “SIEMENS Intelligent Inspection Technologies—On Line Monitor—High Speed Infrared Images of Operating Turbine Blades” (the “Siemens Presentation”), which is incorporated herein by reference. It is noted that the images shown in the Siemens Presentation are of coated components; however, the images can provide a general sense of the spatial resolution and context in which images can be captured using a system in accordance with aspects of the invention. Images of uncoated components can be captured with substantially the same spatial resolution and context. Further, the images convey a sense of the various orientations along which images can be obtained. For example, the images on page 15 shows a radial view along the blade. The system 29 according to aspects of the invention can obtain data in any direction—circumferential, radial or axial. It would not be possible to obtain information along a radial path using a point source scan, line scan or A-scan sensors.

Alternatively or in addition to the image processor 34, the signal processor 32 can be a temperature processor 42. At a minimum, the temperature processor 42 can be adapted to determine the temperatures values 44 across the surface of a component under observation based on the emitted radiance 31 received by the electromagnetic sensor 30.

The signal processor 32 can also be a radiance measurement device 46. Using the radiance 31 received by the electromagnetic sensor 30, the radiance measurement device 46 can quantitatively measure the radiance values 48 across the surface of the component under observation.

The casing 50 or outer portions of the turbine engine 10 can be modified as needed to accommodate components, such as the electromagnetic sensor 30, according to aspects of the invention. For example, one or more viewing ports 52 can be provided. Each port 52 can be located near a component of interest, so that the electromagnetic sensor 30 and/or the borescope 40 can have a direct line of sight to an uncoated component under observation. A portion of the electromagnetic sensor 30 and/or borescope 40 can extend into the turbine engine 10 and can be exposed to the operational environment. A pressure barrier and/or any suitable seal or other system can be used to maintain a pressure boundary between the inside of the turbine engine 10 and the outside. Ideally, the pressure in the turbine is maintained while the sensor 30 and/or borescope 40 are maintained at substantially atmospheric pressure. In one embodiment, the pressure in the port 52 can be greater than the local pressure inside the turbine engine 10 so as to prevent combustion gases or other gases from entering the port 52. The electromagnetic sensor 30 and/or the borescope 40 can be cooled with any suitable fluid, including, for example, air.

According to aspects of the invention, one or more engine operating parameter sensors 56 can be operatively positioned to measure other operational characteristics of the turbine engine 10, including, for example, temperature, speed, fuel consumption and power output. Examples of such sensors include an RPM sensor and a per-rev-signal (sync) sensor. The engine operating parameter sensors 56 can be operatively connected to an engine operating parameter processor 58. The engine operating parameter processor 58 can monitor, continuously or at predetermined intervals, any engine parameters of interest.

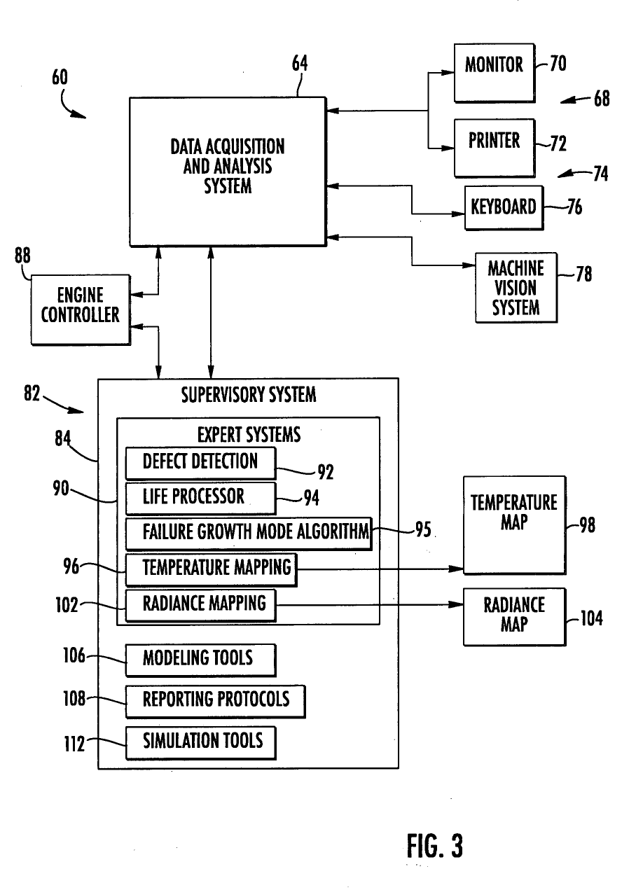

The signal processor 32 and the engine operating parameter processor 58 can be operatively connected to a data collection and analysis system 60. One example of the data collection and analysis system 60 is shown in FIG. 3. The data collection and analysis system 60 can have numerous functions. For example, the data collection and analysis system 60 can collect and store data generated by the electromagnetic sensor 30, the signal processor 32, the engine operating parameter sensor 56 and/or the engine operating parameter processor 58. In one embodiment, the data collection and analysis system 60 can store images 36 generated by the image processor 34, temperature values 44 generated by the temperature processor 42, and/or radiance values 48 computed by the radiance measurement device 46 in any suitable manner such as in one or more databases.

There can be a database associated with each individual component under observation. Such a database can include historical spatial data of radiance for that particular component. Further, the data collection and analysis system 60 can be adapted to retrieve the stored data, as needed. The data collection and analysis system 60 can include any suitable components. For example, data collection and analysis system 60 can include a computer 64.

One or more peripheral devices can be operatively associated with the data collection and analysis system 60. In one embodiment, the peripheral device can be a display 68 operatively associated with the data collection and analysis system 60. The display 68 can be, for example, a monitor 70 and/or a printer 72. Data, such as images 36 generated by the image processor 34, can be presented on the display 68. Further, an operator interface 74, such as a keyboard 76, can be operatively associated with the data collection and analysis system 60. In one embodiment, a machine vision system 78 can be operatively connected with the data collection and analysis system 60.

The data collection and analysis system 60 can be adapted to allow for control of various system components and parameters. To that end, the data collection and analysis system 60 can be equipped with control software. The control software can be used to coordinate the activity of the electromagnetic sensor 30, the signal processor 32, the engine operating parameter sensor 56 and/or the engine operating parameter processors 58. For example, the control software can coordinate image capturing intervals, component selection, focus adjustment, spectral window, pan and tilt, and preprocessing of images. Such coordination can be done real time when the engine is in operation.

It should be noted that the images or data can be captured at any desired interval—daily, monthly, yearly, or even every revolution. Further, in the context of blades, it should be noted that a single blade in a row of blades can be selected, or any combination of a plurality of blades (whether in the same row or in different rows) can be selected. Further, the component under observation can be viewed at any desired time it is within the vantage viewing area. For example, a user may wish to view the component as it enters the vantage viewing area, as it leaves the vantage viewing area, or at any time in between. Capturing images of or collecting data on an uncoated component in as many unique positions as possible can yield more complete information about the component. In the context of a turbine blade, an image captured as the blade enters the vantage viewing area can show and provide information about the leading edge of the blade. An image captured as the blade is leaving the vantage viewing area can show and provide information about the trailing edge of the blade.

In some instances, aspects of the invention can further include a supervisory system 82, which can be a computer 84 equipped with supervisory level software. The supervisory system 82 can be separate from but operatively connected to the data collection and analysis system 60. Alternatively, the supervisory system 82 can be a part of the data collection and analysis system 60, as is shown in FIG. 3. The supervisory level software can allow the supervisory system 82 to perform numerous functions. For example, the supervisory system 82 can be operatively connected to an engine controller 88 so that engine operating parameters can be modified as needed. In one embodiment, the supervisory system 82 can be operatively connected to receive data from the engine operating parameter processor 58. Alternatively, the engine operating parameter processor 58 can be a part of the supervisory system 82.

The supervisory system 82 can include one or more expert systems 90, which can be empirical and/or analytical based and can analyze data received by the data collection and analysis system 60. For example, the expert systems 90 can analyze data from the electromagnetic sensor 30, the signal processor 32, the engine operating parameter sensor 56 and/or the engine operating parameter processor 58 for one or more characteristics or features of an uncoated component under observation. In one embodiment, one of the expert systems 90 can include a defect detection expert system 92 with a failure knowledge base and/or a failure detection algorithm. Thus, by examining an image or other data, the defect detection expert system 92 can identify defects and/or impending failure of the uncoated component under observation. The expert systems can also include knowledge so that, once a defect or failure mode is detected, it can provide suggestions for corrective action. Examples of failures that can be detected by the defect detection expert system 92 can include thermal failure, mechanical failure, metallurgical failure, coating system failure, and foreign and domestic object damage. In one embodiment, the defect detection expert system 92 can analyze one or more images 36 generated by the image processor 34 for indicators of an active failure mode, such as cracks, debonds, hot and cold regions, blocked cooling passages, escaping cooling fluids, dimensional changes or nonconformities.

The expert system 90 can also test any evidence of defects or failure against operating conditions based on data from the engine operating parameter sensors 56 and can determine the relevance of any such evidence of defects or failure. In one embodiment, the expert system 90 can include a life processor 94. The life processor 94 can include analytical and/or empirical models of life consumption for a given component or material in service. Once a defect or a failure has been detected, the life processor 94 can estimate the remaining life of a component under observation or determine the amount of time it will take for a defect to propagate to a critical point.

The expert system 90 can further include a temperature mapping system 96. The temperature mapping system 96 can use temperature data of the surface of the component of interest to create a temperature map 98 of the surface of the component under observation. The temperature data used by the temperature mapping system 96 can come from any of a number of sources. For example, the temperature mapping system 96 can use temperature values 44 computed by the temperature processor 42. Alternatively or in addition, the temperature mapping system 96 can use temperature values calculated by an expert system that includes an algorithm for calculating component surface temperature based on radiance data or measurements.

A surface temperature map 98 of a component under observation can be beneficial to an engine operator for various reasons. For example, it is known that component failure can be directly related to component surface temperature. Thus, the temperature map 98 can be evaluated by an engine operator, machine vision system 78 and/or the expert systems 90 for hot regions on the component surface. If such hot regions are identified, corrective action can be taken if necessary.

In accordance with aspects of the invention, the temperature values, the radiance values, the temperature maps and/or radiance maps can be calibrated. In one embodiment, such calibration can be achieved using a temperature measurement device, such as a thermocouple 54. A shown in FIG. 2, the thermocouple 54 can be attached to or otherwise provided on the surface 19 of the uncoated component under observation so as to be in the field of view of the sensor 30 as the component passages a vantage viewing area. The thermocouple 54 can be operatively connected to the data acquisition and analysis system 60, which can store temperature values generated by the thermocouple 54. The thermocouple 54 can be used to check and/or calibrate data collected by the system 29.

The expert system 90 can further include a radiance mapping system 102. The radiance mapping system 102 can use radiance data of the surface of the component of interest to create a radiance map 104 of the surface of the component under observation. The radiance mapping system 102 can use the radiance values 48 computed by the radiance measurement device 46 to generate the radiance map 104. The radiance map 104 can be a two dimensional map of an entire component or a portion of the component. Such maps can provide sufficient context so a user will be able to discern exactly what is being looked at based on the map alone, giving a user both knowledge and confidence. These maps can eliminate much of the guesswork that has been associated with A-scans, line scans or single point scans, which, as noted above, provide insufficient contextual information and leave a user in doubt as to whether the data collected is even related to the intended target.

The system 29 can further include modeling tools 106, such as thermal models, mechanical models, cooling system models and efficiency models. In one embodiment, the modeling tools 106 can be part of the supervisory system 82. Data collected in accordance with aspects of the invention can be used in these modeling tools 106. It will be appreciated that the system according to aspects of the invention can facilitate analytical model validation and empirical validation of fluid flow, heat transfer, cooling system effectiveness, component and gas velocities, power outputs, combustion, and combustion gas analysis.

The supervisory system 82 can also be equipped with analysis and reporting protocols 108. The supervisory system 82 can control the lower level systems and can report to engine operators the occurrence of certain events, the significance of those events, recommendations on future operation, and ramifications.

Now that the individual components of an evaluation system according to aspects of the invention have been described, various manners of using such a system to non-destructively evaluate uncoated turbine engine components during engine operation will now be described. It is understood that the following description is exemplary, as there are numerous ways in which such a system can be operated in accordance with aspects of the invention.

In one embodiment, an array of electromagnetic sensors 30 can be used to capture an infrared image 36 of a single turbine blade 18 as it passes by a vantage viewing area. Such image capturing can occur at any point during engine operation. The image 36 can be presented on the display 68. The image 36 can be visually examined for one or more features, such as defects 110. The defect 110 can be any of a number of things, including, for example, cracks, delamination, hot regions, cold regions, blocked cooling passages, escaping cooling fluids, localized heating due to frictional rubs, cooling effect from cooling gases, thin film holes, dimensional changes and dimensional nonconformities. In some instances, excessive heat is produced at the defect 110 itself, which can be identified on the image 36. Any of the above examinations can be performed by an engine operator, a machine vision system 78 and/or one or more expert systems 90. The image 36 can be stored in the data collection and analysis system 60 for later retrieval. Engine operating data received from the one or more engine operating parameter sensors 56 and/or the engine operating parameter processor 58 at the moment the image 36 is taken can be stored and associated with the image 36 in the data collection and analysis system 60.

In one embodiment, subsequent images 36 of the same turbine blade 18 can be acquired over a period of time so that there is a plurality of images 36 of the turbine blade 18. The plurality of images 36 can be captured at any suitable interval, preferably over a relatively short time interval. It is noted that images of the turbine blade 18 can but do not have to be captured each time the blade 18 passes the viewing area.

The plurality of images 36 can be stored or immediately presented for review. The plurality of images 36 can be compared to each other with respect to one or more characteristics or features of interest. Such a comparison can be performed by an engine operator, a machine vision system 78 or one of the expert systems 90. By comparing the plurality of images 36, defects, impending failure and/or other changes in the turbine blade 18 can be detected. In one embodiment, the plurality of images 36 can be sequentially presented in a movie-like format so that changes in the component over a period of time can be visually observed.

Thus, it will be appreciated that a system according to aspects of this invention not only allow for the detection of defects, but it also provides the ability to watch the growth of defects or other non-conformities. The system can use expert systems 90 and/or modeling tools 106 to determine when the defect or non-conformity has progressed to a critical point and/or can forecast failure. Based on information or advice from the expert system 90 or based on the judgment of the engine operator, engine operating parameters can be modified or, if necessary, the engine 10 can be shut down.

Alternatively or in addition to capturing images of the turbine blade 18, radiance values 48 measured by the radiance measurement device 46 can be used to detect failure modes. The measured radiance values 48 can be stored by the data collection and analysis system 60. The system according to aspects of the invention can be configured to monitor the radiance values 48 of the turbine blade 18 during engine operation. It is known that local surfaces of failure can exhibit distinctly different radiance than other areas because they have a different emittance or a different temperature. The radiance values 48 can be examined as they are collected. Statistical tools can be employed to analyze the radiance values 48.

Further, an expert system 90 can analyze the radiance values 48 and recognize potential defects based on knowledge of such defect modes. Differences of surface radiance 48 can be noted and tracked in near real-time operation of the turbine blade 18. Additionally, rapid analysis and decision systems utilizing both expert and supervisory subsystems can be employed to summarize data and make decisions regarding the operation of the engine 10. The expert systems 90 can include component life processor 94 and failure mode growth algorithms 95 that can forecast the operating time available once a failure mode is detected. The expert system 90 can have simulation tools 112 that can allow an operator or a computer to change turbine operating parameters and generate estimates of remaining life of the component.

The radiance values 48 and/or the temperature values 44 can be used to detect failure modes in cooled turbine engine components. Critical hot section components are commonly cooled by supplying a coolant to internal cooling passages in the component. If the passages become ineffective for reasons like blockages, wall failure or oxidation, the component life can be diminished. Such changes in the cooling system would directly result in an appreciable change in the surface temperature and/or radiance in the affected area of that component.

Alternatively or in addition, the system 29 according to aspects of the invention can generate temperature maps 98 of the surface 19 of the turbine blade 18. Such temperature maps 98 can be useful because the surface temperature 44 of the turbine blade 18 is directly related to component failure. The temperature maps 98 can be presented on the display 68 as they are generated and/or they can be stored in the data acquisition and analysis system 60. A plurality of temperature maps 98 of the turbine blade 18 can be generated over time.

As noted above, the temperature maps 98 can be compared to detect the formation and progression of potentially critical defects 110, among other things, in near real-time. The temperature maps 98 can be analyzed by one or more expert systems 90 or by an engine operator. The expert systems 90 can track the progression of any defects, estimate remaining component life, notify operations of component conditions, oversee and report on component status and recommend best operating practices. Similarly, the system 29 can evaluate one or more radiance maps 104, as described above.

As noted previously, one or more thermocouples 54 can be used to check and/or calibrate data collected by the system 29. For example, a temperature value measured by the thermocouple 54 can be compared against the temperature value shown on a temperature map substantially at the exact location of the thermocouple 54. If it is assumed that the temperature value of the thermocouple is correct, then the difference between the thermocouple temperature value and the temperature value generated based on the emitted radiance can be used to correct the temperature at the location of the thermocouple. If this temperature differential is assumed to exist across the entire surface of the component, then the temperature values across the temperature map can be normalized. That is, the difference can be applied to all temperature values underlying the temperature map. Such calibration can be performed by the system 29. To that end, the system software can be programmed to take into account such temperature differentials. Further, it will be understood that the above process can also be applied to calibrate any radiance maps generated by the system.

The control software and/or the supervisory software can determine trends or excursions in the collected data and notify or alert the operator of the finding. Different types of preprocessing logic can be used to identify excursions or trends. Raw data signals can be processed as collected. Some preprocessing steps can include a continually updated running average with statistical significance for ongoing data collection, which can establish a baseline for comparison of each refreshed data set. Excursions from this baseline can be brought to the attention and disposition of the expert system 90. Historical averages can be periodically stored for long-term trending and supervisory system disposition. The system can report information in the following categories: temperature maps, remaining component life, recommendations for optimizing specific operating parameters, and emergency alert. By continually monitoring the operating conditions, the remaining life for different future operating conditions can be forecasted. The operator can have the ability to balance power output and component life expense rate based on advice given by the control system software. This will optimize power output and outage scheduling for maximum operator control. The system can provide alarms for critical component loss situations. The alarms can notify operators only in the event of imminent damage or failure. The system can also provide alarm signal outputs for connection to standard tripping control devices for the option of automatic tripping.

It should be noted that infrared transmission, absorption, and emissivity properties of the hot turbine engine gas can be initially calibrated within the range of operating parameters expected. The infrared band can be selected so that hot gas properties above are minimal. Thermal emission characteristics can be determined for several states of the component condition. These characteristics can include emissivity, conductivity, and absorption as a function of temperature and wavelength. Normal changes of the component including surface contamination can be taken into account.

Characteristics of deteriorating turbine engine components can be studied and compared to normal changes in the non-deteriorated state. Uncoated components can be subjected to innocuous contamination, which can influence measured spectral properties. These normal changes can be gradual, and therefore, are expected to cause gradual and accountable changes in the emission of a normal uncoated component. The expert systems 90 can learn to compensate for these changes.

Again, the system and methods in accordance with aspects of the invention are directed to visual-based systems. The images, temperature maps and/or radiance maps captured or generated by the system provide an engine operator with sufficient visual information and context. By providing an image or a map of an entire component or at least a significant portion of the component, an engine operator can readily understand the information presented, thereby minimizing errors and guesswork.

It will be appreciated that the system 29 according to aspects of the invention can have numerous benefits. For instance, the system 29 allows uncoated turbine engine components in a high temperature environment and/or operating high speeds to be monitored and evaluated non-destructively. Thus, the system 29 can minimize the need for costly off-line inspection of these turbine engine components. Further, the system 29 can improve the reliability of turbine engines by the early identification of the need for component maintenance. In addition, with the real time or near real time information provided by the system 29, an engine operator can be alerted within seconds of the detection of a defect or a failure mode. Such advanced warning gives the user time to take corrective action and can minimize potential damage due to component failure and associated downtime. Further, long term failure modes can be tracked over time.

In addition, the system 29 can provide material validation with performance data. Further, the system 29 can provide for design feature validation, which, in turn, can facilitate rapid redesigning. The system 29 can replace current component life assumptions based on equivalent operational hours using actual time and temperature data. These and other benefits can be obtained with the system 29 according to aspects of the invention.

The system 29 according to aspects of the invention can be particularly useful in validating a new design or a design modification. For example, in the context of a blade, a cooling hole can be added. In one embodiment, blades with the new cooling hole can be installed in a test engine. While the engine is running, the system 29 can collect data (including, for example, images, temperature maps and/or radiance maps) on one or more of the blades, particularly in a region including the new cooling hole. These data can be compared to previous data of blades that did not include the new cooling hole. Such prior data may be stored on the data acquisition and analysis system 64, one or more expert systems 90 or other system or database. Thus, the system 29 can facilitate rapid evaluation of whether the new or modified design is an improvement over the prior design.

Alternatively, a blade with the new cooling hole can be installed in a test engine with other blades that do not have the new cooling hole. While the engine is running, the system 29 can collect data on the blade with the cooling hole and one or more of the blades without the cooling hole at substantially the same time. Such data can be compared to determine whether the new or modified design is an improvement over the prior design.

The foregoing description is provided in the context of one possible system and method. Thus, it will of course be understood that the invention is not limited to the specific details described herein, which are given by way of example only, and that various modifications and alterations are possible within the scope of the invention as defined in the following claims.

What is claimed is:

1. A non-destructive on-line evaluation system for a turbine engine comprising:
an on-line turbine engine;
an uncoated component inside the turbine engine, the uncoated component emitting radiance energy;
an electromagnetic sensor positioned to receive radiance energy emitted from the uncoated component, the electromagnetic sensor producing signals in response to receiving radiance energy, wherein the electromagnetic sensor is located remotely from the uncoated component such that there is no contact between the electromagnetic sensor and the component, wherein the electromagnetic sensor is adapted to receive electromagnetic energy from about 0.38 to about 15 μm;
a signal processor operatively connected to receive signals from the electromagnetic sensor, wherein the signal processor converts the signals into data, wherein the data is at least one of an image of the uncoated component, a temperature value and a radiance value.

2. The system of claim 1 wherein the electromagnetic sensor is a focal plane array sensor.

3. The system of claim 1 wherein the electromagnetic sensor receives radiance energy at wavelengths from about 0.6 μm to about 2 μm.

4. The system of claim 1 further including a data acquisition and analysis system operatively connected to receive data from the signal processor, wherein the data acquisition and analysis system stores the data.

5. The system of claim 4 further including an expert system operatively connected to the data acquisition and analysis system, wherein the expert system analyzes data stored by the data acquisition and analysis system.

6. The system of claim 5 wherein the signal processor generates images of the uncoated component, wherein the expert system includes a defect detection system that analyzes at least one of the images to identify any defects associated with the uncoated component.

7. The system of claim 6 wherein the expert system includes a life processor, wherein the life processor estimates the remaining life of the uncoated component.

8. The system of claim 5 wherein the signal processor generates temperature values, wherein the expert system includes a temperature mapping system, wherein the temperature mapping system generates a temperature map of a surface of the uncoated component based on the temperature values.

9. The system of claim 5 wherein the signal processor generates radiance values, wherein the expert system includes a radiance mapping system, wherein the radiance mapping system generates a radiance map of a surface of the uncoated component based on the radiance values.

10. A method of non-destructively evaluating uncoated turbine engine components during engine operation comprising:
operating a turbine engine, the turbine engine having an uncoated component;
capturing a first image of the uncoated component while the turbine engine is operating; and
displaying the first image to a user.

11. The method of claim 10 further including the step of evaluating the first image of the uncoated component to identify a failure mode associated with the uncoated component.

12. The method of claim 10 further including the steps of:
capturing a plurality of subsequent images of the uncoated component over a period of time;
sequentially displaying the first image and the plurality of subsequent images of the uncoated component;
evaluating the displayed images to identify a failure mode associated with the uncoated component.

13. The method of claim 12 wherein the comparing step is performed by at least one of an engine operator, a machine vision system and an expert software system.

14. The method of claim 12 wherein a failure mode is identified, and further including the steps of:
estimating one of the remaining life of the uncoated component and the remaining operating time available;
generating an output corresponding to at least one of the remaining life of the uncoated component and the remaining operating time available.

15. The method of claim 12 wherein the first and subsequent images are captured at wavelengths from about 0.6 μm to about 2 μm.

16. A method of non-destructively evaluating an uncoated turbine engine component comprising:
operating a turbine engine, the turbine engine having an uncoated component with a surface;
receiving radiance energy emitted from an area of the surface of the uncoated component at a first time;
determining a plurality of first temperature values across the area based on the radiance energy received from the uncoated component at the first time; and
generating a first temperature map of the area at the first time based on the plurality of first temperature values.

17. The method of claim 16 further including the steps of:
receiving radiance energy emitted from the area of the uncoated component at a subsequent time;
determining a plurality of subsequent temperature values across the area based on the radiance energy received from the uncoated component at the subsequent time; and
generating a subsequent temperature map of the area at the subsequent time based on the plurality of subsequent temperature values.

18. The method of claim 17 further including the steps of:
evaluating at least one of the first temperature map and the subsequent temperature map to identify a failure mode associated with the uncoated component in the area.

19. The method of claim 16 wherein the radiant energy is received at wavelengths from about 0.6 μm to about 2 μm.

20. The method of claim 16 further including the steps of:
providing a temperature measurement device at a first position on the surface of the uncoated component, wherein the first position is located in the area;
measuring a temperature value at the first position using the temperature measurement device at the first time;
determining the difference between the temperature value measured by the temperature measurement device and at least one of the first temperature values in the area substantially at the first position; and
generating an output corresponding to the determined difference.
